(19) United States
(12) Patent Application Publication
(10) Pub. No.: US 2012/0180853 A1
(43) Pub. Date: Jul. 19, 2012

(54) Photovoltaic Cells

(75) Inventor: José BRICEÑO, Ohta-Ku (JP)

(73) Assignee: SI-NANO, INC., BURLINGAME, CA (US)

(21) Appl. No.: 13/348,499

(22) Filed: Jan. 11, 2012

Related U.S. Application Data
(60) Provisional application No. 61/433,185, filed on Jan. 14, 2011.

(51) Int. Cl. H01L 31/02; H01L 31/18; H01L 31/20

(52) U.S. Cl. 136/252; 438/96; 438/97; 438/98; 257/E31.044; 257/E31.048; 257/E31.011

(57) ABSTRACT

A photovoltaic structure having a semiconductor substrate, and metal particles bonded to the semiconductor substrate. The photovoltaic structure is sufficiently thin to be translucent or semitransparent. The metal particles are produced when a layer of metal is deposited onto the semiconductor substrate and heated. The photovoltaic structure is capable of causing generation of an electrical current upon exposure to electromagnetic radiation within one or more of the infrared spectrum, the visible light spectrum, or the ultraviolet spectrum.

### CROSS-REFERENCE TO RELATED APPLICATIONS

The present application claims the benefit of priority of U.S. Provisional Patent Application No. 61/433,185, filed on Jan. 14, 2011.

### FIELD

The present invention relates generally to photovoltaic cells, and more particularly but not exclusively to the manufacture of thin film photovoltaic cells that are highly efficient and economical to produce.

### BRIEF SUMMARY

In accordance with an embodiment of the present invention, a method for constructing a photovoltaic cell is provided, the method includes: depositing a first layer of metal onto a semiconductor substrate by one or more of sputtering, vapor deposition, or printing; and heating the first layer of metal and the semiconductor substrate at a temperature in the range between 400 and 1200 degrees Celcius to produce a first plurality of metal particles bonded to the semiconductor substrate, whereby the photovoltaic structure produced by the depositing and the heating is capable of causing generation of an electrical current upon exposure to electromagnetic radiation within one or more of the infrared spectrum, the visible light spectrum, or the ultraviolet spectrum.

In accordance with an embodiment of the invention, a photovoltaic structure comprises a semiconductor substrate; and a first plurality of metal particles bonded to the semiconductor substrate, whereby the photovoltaic structure is capable of causing generation of an electrical current upon exposure to electromagnetic radiation within one of the infrared spectrum, the visible light spectrum, or the ultraviolet spectrum. In one embodiment, the photovoltaic structure is translucent or semitransparent.

In addition, a photovoltaic cell provides improved characteristics, the photovoltaic cell includes a semiconductor substrate, and a particle surface, wherein the particle surface is between 0.001 and 100 micrometers in thickness.

Other and further features and advantages of the present invention will be apparent from the following descriptions of the various embodiments when read in conjunction with the accompanying drawings. It will be understood by one of ordinary skill in the art that the following embodiments are provided for illustrative and exemplary purposes only, and that numerous combinations of the elements of the various embodiments of the present invention are possible.

### BRIEF DESCRIPTION OF THE DRAWINGS

Non limiting and non exhaustive embodiments of the present invention are described with reference to the following drawings. In the drawings, like reference numerals refer to like parts throughout the various figures unless otherwise specified.

For a better understanding of embodiments of the present invention, reference is made to the following Detailed Description, which is to be read in association with the accompanying drawings, wherein:

FIG. 1 depicts a side view of a photovoltaic cell in accordance with an embodiment of the present invention;

FIG. 2 shows an upper surface of a photovoltaic cell, depicting a particle surface in accordance with an embodiment of the present invention;

FIG. 3 illustrates electrodes along the upper surface of an exemplary photovoltaic cell to measure the I-V characteristics in accordance with an embodiment of the present invention;

FIG. 4 illustrates a side view of an exemplary photovoltaic cell configured for testing in accordance with an embodiment of the present invention;

FIG. 5 illustrates exemplary photovoltaic cell characteristics in accordance with an embodiment of the present invention; and

FIG. 6 illustrates an embodiment of a process for manufacturing a photovoltaic cell in accordance with an embodiment of the present invention.

### DETAILED DESCRIPTION OF PREFERRED EMBODIMENTS

The embodiments of the present invention are described more fully hereinafter with reference to the accompanying drawings, which form a part hereof, and which show, by way of illustration, specific exemplary embodiments by which the invention may be practiced. This invention may, however, be embodied in many different forms and should not be construed as limited to the embodiments set forth herein; rather, these embodiments are provided so that this disclosure will be thorough and complete, and will fully convey the scope of the invention to those skilled in the art. As used herein, the term “or” is an inclusive “or” operator, and is equivalent to the term “and/or,” unless the context clearly dictates otherwise. The term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.” The term “coupled” implies that the elements may be directly connected together or may be coupled through one or more intervening elements.

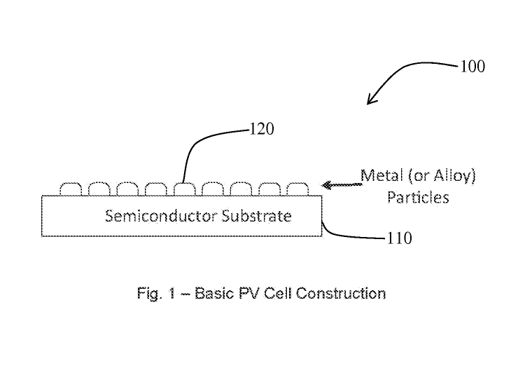

FIG. 1 illustrates the construction of an exemplary photovoltaic (PV) cell 100. The PV cell is constructed on a semiconductor substrate. A base structure is provided on which a lower substrate is comprised from a semiconductor substrate 110. A semiconductor substrate is coupled to an upper surface of the base structure. Adjacent to the upper surface of the semiconductor substrate, is a manufactured series of particles 120. The particles may be comprised of a single metal, a semi-metal, a semiconductor, an alloy metal, an inter-metallic compound, or the combination of all the above.

The semiconductor substrate may be any thickness. Preferably, the semiconductor substrate thickness is 10 nanometers to 500 micrometers and is preferable in the range of a few hundred nanometers. While traditionally some PV cells are comprised from potentially poisonous compounds, no such materials are used in the embodiments of the present invention. Rather, the semiconductor is comprised of materials such as amorphous silicon, polycrystalline silicon, single crystal silicon, or the like. Further, while doping may be used to introduce impurities to improve efficiency, this is not necessary for the embodiment disclosed herein. There may or may not be doping.

The particles introduced to an upper surface of the semiconductor substrate may vary in size from 0.001 to 50 micrometers. In an embodiment, the particles are evenly distributed on the upper surface of the semiconductor substrate and are spaced 0.001 to 100 micrometers apart.

Electrodes are then placed on the upper surface of the particle surface to collect the energy. Preferably, the total thickness of the PV cell is 100 nanometers to 500 micrometers, Because the PV cell can be constructed to be very thin, as compared with the legacy cells, the constructed PV cell is almost translucent, or semitransparent.

In accordance with an embodiment of the present invention, the PV cell construction is not a layered process per se. Particles are placed on the upper surface of the semiconductor substrate.

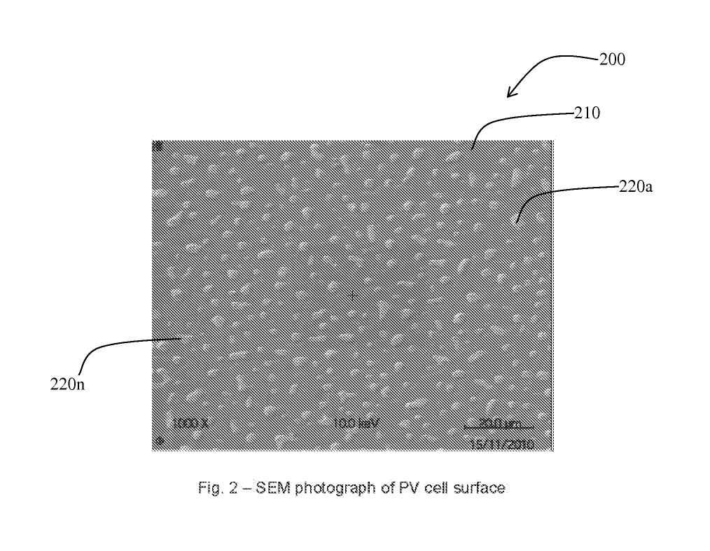

FIG. 2 depicts an exemplary PV cell surface 200. Shown in FIG. 2 is a scanning electron microscope photograph of the surface of the PV cell 200. FIG. 2 shows the basic substrate 210, which is the darker surface, the flat surface, which is essentially the surface of the semiconductor substrate. Adjacent to the upper surface of the semiconductor substrate 210 are a series of particles 220. The particles 220 are spaced about a few microns apart from one another, so distribution of the particles is on the micrometer level, not in the nanometer level. The particles may vary in shape and size in an embodiment the particles are between 1 to 10 microns in diameter. While preferred embodiment may comprise the particles as specified herein, this is not intended to be a limitation on the embodiments and other particles shapes and sizes are contemplated within the scope of the embodiments.

An analysis of the particles shows the particles are preferably comprised from metal or an alloy as described above. The semiconductor substrate is comprised from conventional materials, crystalline inorganic solids, for example, silicon and gallium. The particles are comprised of a metal component, for example, silver, gold, platinum, copper, palladium, cobalt, titanium, tungsten, nickel, chromium, and aluminum.

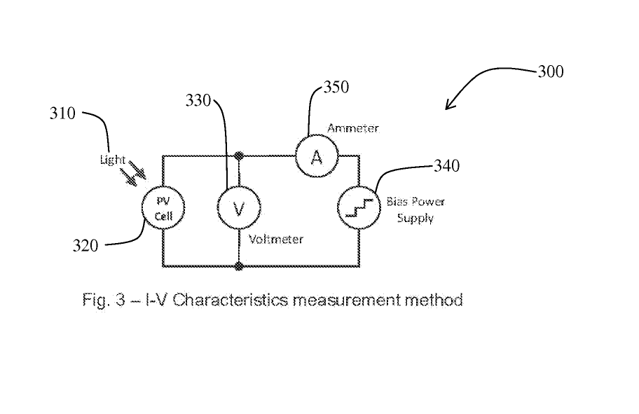

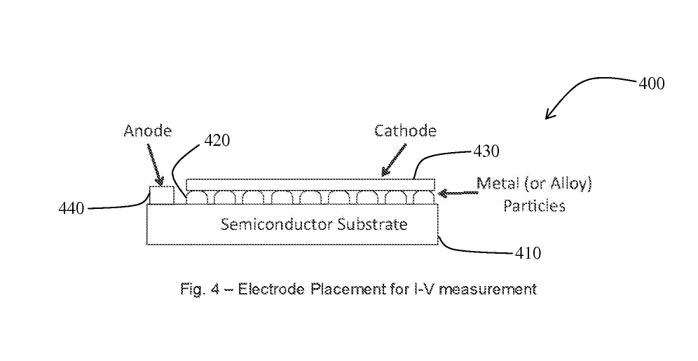

Once constructed, the photovoltaic cell has particular characteristics. Using standard techniques, these characteristics are measured. FIG. 3 illustrates the measurement method 300 of a PV cell. As shown, light 310 is applied to the particle surface of a PV cell 320. A voltmeter 330 is used to measure the potential difference in the PV cell. A bias voltage 340 is applied to the device and an ammeter 350 measures the generated electric current. FIG. 4 depicts a PV cell 400 in its test condition. The PV cell has a semiconductor substrate 410 with particles 420 adjacent to the upper surface of the semiconductor substrate 410. In order to measure the photovoltaic characteristics, in addition to the already described cell, a cathode 430 is placed on the upper surface of the particles 420 and an anode 440 is placed directly on the semiconductor substrate 410. A power supply (not shown) is applied between the cathode 430 and the anode 440.

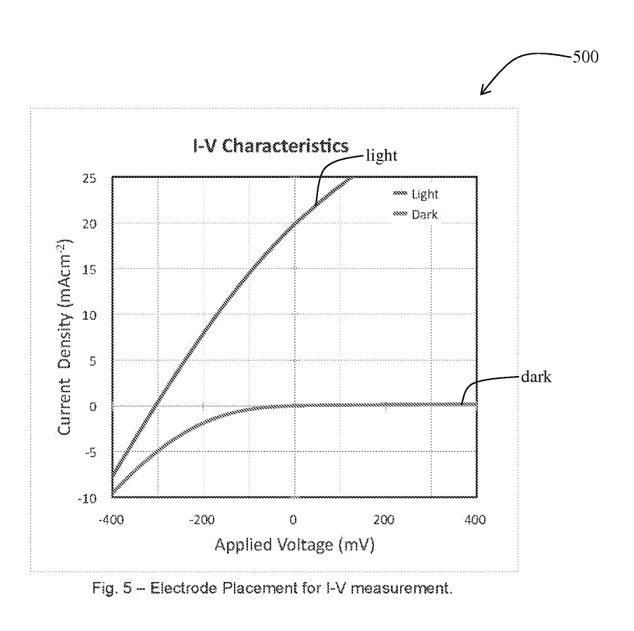

The testing is performed in a conventional manner in order to measure the photovoltaic characteristics of the material. A voltage is applied in the range of −2 volts to +2 volts. From this a series of current measurements are obtained. For example, when 0 volts are applied to the cell, current is generated in accordance with FIG. 5. FIG. 5 depicts an I-V data chart 500. The chart shows the current density versus the applied voltage for one embodiment of a PV cell. In an embodiment, preliminary test results indicate that photovoltaic characteristics are around 20 mA/cm².

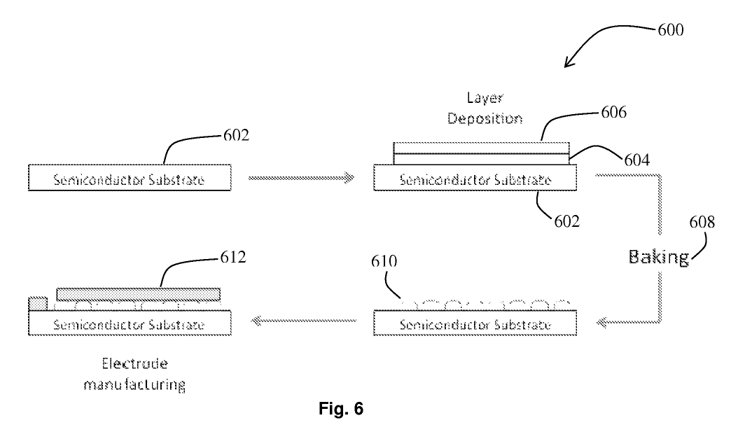

The photovoltaic cell herein may be manufactured in a variety of ways. FIG. 6 illustrates one process 600 for manufacturing a cell. The process begins with the development of a semiconductor substrate 602. A layer of metal (or alloy, etc.) 604 is deposited on top of the semiconductor substrate 602. This depositing process may be achieved by several methods including, but not limited to, sputtering, vapor deposition (VP), and printing. An additional metal (or alloy, etc.) 606 is then deposited on top of the first layer 604 using similar method as above. It is contemplated within the scope of the embodiments that the method for deposit may be the same for both layers or may be different. After the second layer is deposited, the cell is baked 608. The baking process or conditions may vary depending on the specific materials used to construct the cell (semiconductor, metal, alloys, semimetals). The baking temperature can vary from 400 to 1200 Celsius, and the baking time may vary from a few minutes to a few hours, also depending on the materials used. As a result of the baking processes, the layers become particles 610. After baking the electrodes are placed 612.

In an embodiment, two layers of material are deposited over the semiconductor substrate. The first layer may be a metal (such as nickel, cobalt, or copper). The second deposited layer may be a second metal (such as silver, gold). This combination of layers is not intended to be a limitation on the embodiments of the present invention and it is contemplated that the layers may comprise the same or different materials and may be metals or alloys. In an embodiment, both layers are manufactured using standard sputtering techniques, for example, RF, DC, or VP. The thickness of each layer may vary, preferably, the first layer is 5 to 20 nanometers and the second layer is 20 to 200 nanometers. While an embodiment may be the thickness specified herein, this is not intended to be a limitation on the embodiments and other thickness as described above are contemplated within the scope of the embodiments.

Subsequently a baking process is performed to manufacture the particles on top of the semiconductor substrate. Preferably, the baking temperatures are between 600 and 1100 degrees Celsius, depending on the metal components and the baking time is 20 to 60 minutes, depending on the material and the initial layer thickness. While an embodiment may be put through the baking process as just described, this is not intended to be a limitation on the embodiments and other baking temperatures and times as described above are contemplated within the scope of the embodiments.

The electrodes, such as ones like cathode 430 and anode 440, are then constructed. An electrode located on the upper surface of the particles is best constructed using a layer of TCO (transparent conductive oxide) or ITO (Indium tin oxide). The opposing electrode may be constructed using standard techniques to manufacture ohmic contacts on the semiconductor substrate. In an embodiment the ohmic contacts are aluminum. In another embodiment, the ohmic contacts are nickel. While an embodiment of the ohmic contacts may comprise the materials specified herein, this is not intended to be a limitation on the embodiments and other materials are contemplated within the scope of the embodiments.

The novel PV cell described herein has many advantages over those currently available, including but not limited to the following.

First, as all of the materials used in the construction of the photovoltaic cells described herein are inert, no poisonous or carcinogenic materials are implemented as is used in conventional PV cells. This is distinct from the high-efficiency cells that are in the market today.

Second, because of the nature of the construction, the PV cells can be extremely thin, a few hundred nanometers or less. As a result of this, it is very easy to control the transmission of light through the material, so the cell may be translucent. The cell is like an opaque film that can be seen through. This unique characteristic allows it to be applied to a variety of surfaces including windows. Therefore, embodiments of the present invention allow for power generating windows for example on a house, on a car, or on a building. The cells may be applied in a variety of configurations that are not possible with conventional PV cells.

Another advantage and novelty of the construction presented herein is that the manufacturing process is simple, straightforward, and inexpensive. The novel process presented herein is estimated to be as much as 10 to 100 times cheaper than any other manufacturing process of the same kind of PV cells in the market today, this contributes to its novelty and causes it to be revolutionary.

In addition, the amount of energy generated is dependant on the surface of the cell that is how large or small the surface is. It is contemplated within the scope of the embodiments of the present invention that the surface area may vary. Moreover, as efficiency of the PV cell increases, it is contemplated that smaller surface areas may be developed.

In another embodiment, the PV cell produces electricity from light not only in the visible light range, which is between 0.4 micron wavelengths to about 1.1 micron, but it can also produce electricity from infrared light spectrum and from UV light.

As noted previously the forgoing descriptions of the specific embodiments are presented for purposes of illustration and description. They are not intended to be exhaustive or to limit the invention to the precise forms disclosed and obviously many modifications and variations are possible in view of the above teachings, including equivalents. The embodiments were chosen and described in order to explain the principles of the invention and its practical applications, to thereby enable those skilled in the art to best utilize the invention and various embodiments thereof as suited to the particular use contemplated.

What is claimed is:

1. A photovoltaic structure which comprises:
a semiconductor substrate; and
a first plurality of metal particles bonded to the semiconductor substrate,
whereby the photovoltaic structure is capable of causing generation of an electrical current upon exposure to electromagnetic radiation within one or more of the infrared spectrum, the visible light spectrum, or the ultraviolet spectrum.

2. The photovoltaic structure of claim 1, wherein the photovoltaic structure is translucent or semitransparent.

3. The photovoltaic structure of claim 1, wherein the first plurality of metal particles are produced by:
depositing a first layer of metal onto the semiconductor substrate by one or more of sputtering, vapor deposition, or printing; and
heating the photovoltaic structure at a temperature in the range between 400 and 1200 degrees Celcius.

4. The photovoltaic structure of claim 3, wherein the first layer of metal comprises one or more of nickel, copper, or cobalt.

5. The photovoltaic structure of claim 3, wherein the first layer of metal has a thickness in the range between 5 and 20 nanometers.

6. The photovoltaic structure of claim 1, which further comprises a second plurality of metal particles, wherein the first plurality of metal particles and the second plurality of metal particles are produced by:
depositing a first layer of metal onto the semiconductor substrate by one or more of sputtering, vapor deposition, or printing;
depositing a second layer of metal onto the first layer of metal by one or more of sputtering, vapor deposition, or printing; and
heating the photovoltaic structure at a temperature in the range between 400 and 1200 degrees Celcius.

7. The photovoltaic structure of claim 6, wherein the first and the second plurality of metal particles comprise one or more of silver, gold platinum, copper, palladium, cobalt, titanium, tungsten, nickel, chromium and aluminum.

8. The photovoltaic structure of claim 6, wherein the first layer of metal has a thickness in the range between 5 and 20 nanometers, and wherein the second layer of metal has a thickness in the range between 20 to 200 nanometers.

9. The photovoltaic structure of claim 1, wherein the semiconductor substrate has a thickness in the range between 10 nanometers and 500 micrometers.

10. The photovoltaic structure of claim 1, wherein the semiconductor substrate comprises silicon, including one or more of amorphous silicon, polycrystalline silicon, or single crystal silicon.

11. The photovoltaic structure of claim 1, wherein any of the particles of the first plurality of metal particles have a size in the range between 0.001 micrometers and 50 micrometers.

12. The photovoltaic structure of claim 1, wherein the first plurality of metal particles are evenly distributed on the substrate.

13. The photovoltaic structure of claim 1, wherein the first plurality of metal particles have a spacing in the range of 0.001 micrometers to 100 micrometers between particles.

14. The photovoltaic structure of claim 1, wherein the photovoltaic structure has a thickness in the range between 100 nanometers and 500 micrometers.

15. A method for producing a photovoltaic structure comprising:
depositing a first layer of metal onto a semiconductor substrate by one or more of sputtering, vapor deposition, or printing; and
heating the first layer of metal and the semiconductor substrate at a temperature in the range between 400 and 1200 degrees Celcius to produce a first plurality of metal particles bonded to the semiconductor substrate,
whereby the photovoltaic structure produced by the depositing and the heating is capable of causing generation of an electrical current upon exposure to electromagnetic radiation within one or more of the infrared spectrum, the visible light spectrum, or the ultraviolet spectrum.

16. The method of claim 15, wherein the photovoltaic structure is translucent or semitransparent.

17. The method of claim 15, wherein the first layer of metal comprises one or more of nickel, copper, or cobalt.

18. The method of claim 15, wherein the first layer of metal has a thickness in the range between 5 and 20 nanometers.

19. The method of claim 15, further comprising:
depositing a second layer of metal onto the first layer of metal by one or more of sputtering, vapor deposition, or printing; and
the heating step further comprising heating the second layer of metal and the semiconductor substrate at a temperature in the range between 400 and 1200 degrees Celcius to produce a second plurality of metal particles bonded to the semiconductor substrate.

20. The method of claim 19, wherein the first layer of metal has a thickness in the range between 5 and 20 nanometers, and wherein the second layer of metal has a thickness in the range between 20 to 200 nanometers.

21. The method of claim 15, wherein the semiconductor substrate has a thickness in the range between 10 nanometers and 500 micrometers.

22. The method of claim 15, wherein the semiconductor substrate comprises silicon, including one or more of amorphous silicon, polycrystalline silicon, or single crystal silicon.

23. The method of claim 15, wherein any of the particles of the first plurality of metal particles have a size in the range between 0.001 micrometers and 50 micrometers.

24. The method of claim 15, wherein the first plurality of metal particles are evenly distributed on the substrate.

25. The method of claim 15, wherein the first plurality of metal particles have a spacing in the range of 0.001 micrometers to 100 micrometers between particles.

26. The method of claim 15, wherein the photovoltaic structure has a thickness in the range between 100 nanometers and 500 micrometers.
